(19) United States
(12) Patent Application Publication
(10) Pub. No.: US 2020/0144111 A1
(43) Pub. Date: May 7, 2020

(54) METAL INTERCONNECTION STRUCTURE AND METHOD FOR FABRICATING SAME

(71) Applicant: Wuhan Xinxin Semiconductor Manufacturing Co., Ltd., Wuhan (CN)

(72) Inventors: Guangjie XUE, Wuhan (CN); Yun LI, Wuhan (CN); Jun ZHOU, Wuhan (CN)

(21) Appl. No.: 16/250,594

(22) Filed: Jan. 17, 2019

(30) Foreign Application Priority Data
Nov. 5, 2018 (CN) 201811308906.4

(51) Int. Cl. H01L 21/768; H01L 21/311; H01L 21/308; H01L 23/522; H01L 23/532

(52) U.S. Cl. CPC H01L 21/76877; H01L 21/31144; H01L 23/53228; H01L 21/76802; H01L 23/5226; H01L 21/3086

(57) ABSTRACT

A metal interconnection structure and a method for fabricating same are disclosed. The method includes: providing a substrate; sequentially forming a first insulating layer and a dielectric layer on the substrate; forming multiple first recesses in the dielectric layer, the first recesses exposing a portion of the first insulating layer; forming a second insulating layer, the second insulating layer covering sidewalls and a bottom of the first recesses; etching the second insulating layer in the first recesses, the first insulating layer, and a portion of the substrate to form second recesses, a top surface of the second insulating layer on the sidewall of the second recess being lower than a top surface of the second recess such that an opening size at a top of the second recess is larger than opening sizes at remaining position thereof; and forming a metal layer in the second recesses.

### CROSS-REFERENCE TO RELATED APPLICATION

This application claims the priority of Chinese patent application number 201811308906.4, filed on Nov. 5, 2018, the entire contents of which are incorporated herein by reference.

### TECHNICAL FIELD

The present invention relates to the technical field of semiconductor fabrication, and in particular, to a metal interconnection structure and a method for fabricating same.

### BACKGROUND

A metal interconnection structure is an indispensable structure for a semiconductor device. In a semiconductor fabrication process, the quality of the formed metal interconnection structure has a great influence on the performance of the semiconductor device and the semiconductor fabrication cost.

In a metal interconnection structure fabrication method of the prior art, generally, a dielectric layer is first deposited on a semiconductor device structure, a pattern of a recess or a contact hole is then formed by etching, and metal is finally deposited on the structure in which recesses or contact holes are formed. The recesses or the contact holes are filled with the metal.

However, the growth and filling of the metal are mostly implemented by means of physical deposition, and overhangs will be formed at the top of the dielectric layer due to inherent isotropic properties. With the development of a semiconductor technology toward a smaller size, the properties become more and more sensitive, and the metal filling is extremely easy to form cavities in the recesses or the contact holes due to sealing caused by the overhangs, thereby greatly affecting the performance of the semiconductor device.

Therefore, it is desirable to provide a metal interconnection structure fabrication method and a metal interconnection structure capable of effectively eliminating cavities in a recessed portion of a metal interconnection structure.

### SUMMARY OF THE INVENTION

Based on the problem described above, the objective of the present invention is to provide a metal interconnection structure and a method for fabricating same, thereby reducing the occurrence of cavity defects and improving the performance of a semiconductor device.

In order to achieve the above objective, the present invention provides a method for fabricating a metal interconnection structure, including:

providing a substrate, and sequentially forming a first insulating layer and a dielectric layer overt the substrate;

forming a plurality of first recesses in the dielectric layer, each of the plurality of first recesses exposing a portion of the first insulating layer;

forming a second insulating layer, the second insulating layer covering sidewall and a bottom of each of the plurality of first recesses;

etching, in plurality of the first recesses, the second insulating layer, the first insulating layer, and a portion of the substrate to form a plurality of second recesses; a top surface of the second insulating layer on the sidewall of the second recess being lower than a top surface of the second recess such that an opening size at a top of the second recess is larger than opening sizes at remaining position of the second recess; and

forming a metal layer in the plurality of second recesses.

Optionally, before forming the metal layer, the method for fabricating a metal interconnection structure further includes: forming a block layer on sidewalls and a bottom of each of the plurality of second recesses.

Optionally, in the method for fabricating a metal interconnection structure, forming a metal layer includes the step of:

filling the plurality of second recesses with the metal layer, the metal layer also covering the dielectric layer; and

planarizing the metal layer to expose the second insulating layer.

Optionally, in the method for fabricating a metal interconnection structure, a material of the first insulating layer is same as a material of the second insulating layer.

Optionally, in the method for fabricating a metal interconnection structure, each of the first and second insulating layers is a silicon nitride layer, the dielectric layer is a silicon oxide layer.

Optionally, in the method for fabricating a metal interconnection structure, forming the plurality of first recesses includes the step of:

sequentially forming a hard mask layer and a patterned photoresist layer over the dielectric layer;

etching the hard mask layer, by using the patterned photoresist layer as a mask, to form a plurality of openings exposing the dielectric layer;

removing the patterned photoresist layer;

etching the dielectric layer, by using the hard mask layer in which the plurality of openings are formed as a mask, to form the multiple first recesses; and

removing the hard mask layer.

Optionally, in the method for fabricating a metal interconnection structure, the dielectric layer is completely etched away to form the plurality of first recesses.

Correspondingly, the present invention also provides a metal interconnection structure, including:

a substrate;

a first insulating layer and a dielectric layer sequentially located on the substrate, a plurality of first recesses formed in the dielectric layer, the plurality of first recesses exposing the first insulating layer;

a second insulating layer located on sidewalls of each of the plurality of first recesses, a top surface of the second insulating layer being lower than a top surface of the first recess;

a plurality of second recesses formed in the first recesses, wherein each of the second recess penetrates through the first insulating layer and extends into the substrate, an opening size at a top of each second recess being larger than opening sizes at remaining positions of the second recess; and

a metal layer located in the plurality of second recesses.

Optionally, the metal interconnection structure further includes: a block layer located on sidewalls and a bottom of the plurality of second recesses.

Optionally, in the metal interconnection structure, a material of the first insulating layer is same as a material of the second insulating layer.

Correspondingly, the present invention also provides a metal interconnection structure, including:

a substrate;

a first insulating layer and a dielectric layer sequentially located on the substrate; a plurality of first recesses formed in the dielectric layer, the plurality of first recesses exposing the first insulating layer;

a second insulating layer located on sidewalls of the plurality of first recesses;

multiple second recesses formed in the first recesses, wherein each of the plurality of second recesses penetrates through the first insulating layer and extends into the substrate;

and a metal layer located in the plurality of second recesses.

Compared to the prior art, in the metal interconnection structure and the method for fabricating same provided by the present invention, after first recesses exposing a first insulating layer are formed, a second insulating layer is firstly formed on the sidewalls and bottoms of the first recesses. Then the second insulating layer in the first recesses, the first insulating layer, and a portion of a substrate are etched away to form second recesses. The top surface of the insulating layer on the sidewall of the second recess is lower than the top surface of the second recess such that an opening size at the top of the second recess is larger than opening sizes at the remaining positions. When the metal layer is formed in the second recesses, since the opening size at the top is increased, a window for an overhang effect at the top during metal filling can be enlarged such that the possibility of cavity formation is reduced and the performance of the semiconductor device is improved.

Furthermore, the second insulating layer is formed on the sidewalls of the second recesses, i.e., the metal layers filled in the adjacent second recesses are isolated by not only the dielectric layer but also the second insulating layer. Therefore, the diffusion of metal in the metal layers can be better avoided, and the pressure resistance of the metal interconnection structure can be increased. In addition, due to the increase in the opening size at the top of the second recess, the process capability of a metal filling machine can be increased.

### BRIEF DESCRIPTION OF THE DRAWINGS

FIGS. 1-5 are schematic structural diagrams of steps of an existing method for fabricating a metal interconnection structure.

FIG. 6 is a flowchart of a method for fabricating a metal interconnection structure according to an embodiment of the present invention.

FIGS. 7-13 are schematic structural diagrams of steps of a method for fabricating a metal interconnection structure according to an embodiment of the present invention.

### DETAILED DESCRIPTION

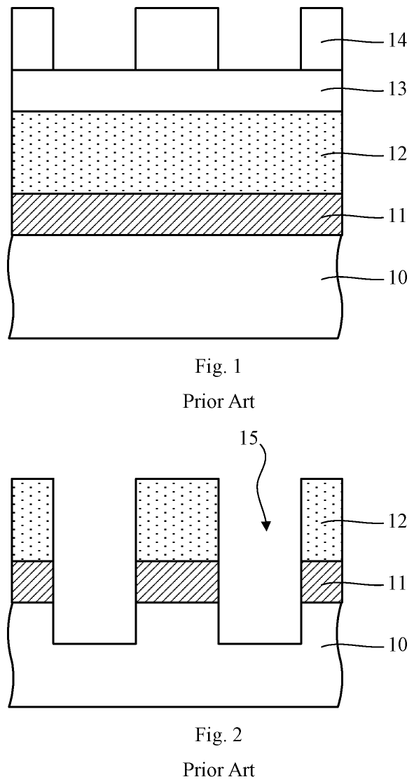

FIGS. 1-5 are schematic structural diagrams of steps of an existing method for fabricating a metal interconnection structure. Referring to FIGS. 1-5, the method for fabricating a metal interconnection structure is specifically as follows.

First, referring to FIG. 1, a substrate 10 is provided. An insulating layer 11, a dielectric layer 12, and a hard mask layer 13 are formed on the substrate 10 sequentially. Then, a photoresist layer is formed over the hard mask layer 13. The photoresist layer is exposed and developed to form a patterned photoresist layer 14, so that predetermined regions of the hard mask layer 13 where recesses are to be formed are exposed. Subsequently, the hard mask layer 13 is etched by using the patterned photoresist layer 14 as a mask so as to form openings in the hard mask layer 13. Afterward, the patterned photoresist layer is removed. The dielectric layer 12, the insulating layer 11 and a portion of the substrate 10 are etched away by using the hard mask layer 13 as a mask so as to form recesses 15. Finally, the hard mask layer 13 is removed to form the structure as shown in FIG. 2.

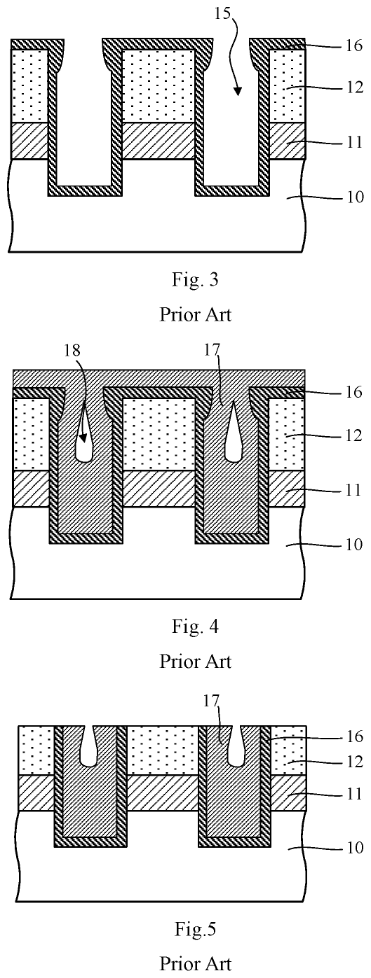

Next, a block layer 16 is formed over the sidewalls and bottoms of the recesses 15. In the process of forming the block layer 16, an overhang effect is caused at the top of the sidewall of the recess 15 due to isotropic properties, i.e., an overhang is formed at the top of the sidewall of the recess 15. That is, the thickness of the block layer 16 at the top of the sidewall of the recess 15 is larger than that of the block layer 16 at the remaining positions of the sidewall of the recess 15, such that an opening size at the top of the recess 15 is smaller than opening sizes at the remaining positions, as shown in FIG. 3.

Subsequently, a metal seed layer (not shown) is formed over the sidewalls and bottoms of the recesses 15. In this process, the overhang effect is also caused at the top of the sidewall of the recess 15, i.e., an overhang is formed at the top of the sidewall of the recess 15, such that the opening size at the top of the recess 15 is further reduced. Finally, a metal layer 17 is formed in the recesses 15, for example, by electroplating. In the formation process, it is extremely easy to form a cavity 18 in the recess due to sealing caused by the overhangs, as shown in FIG. 4.

Finally, the metal layer 17 is planarized to expose the dielectric layer 12. As shown in FIG. 5, the recesses are not fully filled with the metal layer 17, thus causing influence on the performance of a semiconductor device.

In view of the problem above, the inventor of the present application provides a method for fabricating a metal interconnection structure, including: providing a substrate, and sequentially forming a first insulating layer and a dielectric layer over the substrate; forming multiple first recesses in the dielectric layer, the first recesses exposing a portion of the first insulating layer; forming a second insulating layer, the second insulating layer covering the sidewalls and bottoms of the first recesses; etching the second insulating layer in the first recesses, the first insulating layer, and a portion of the substrate to form second recesses; the top surface of the second insulating layer over the sidewall of each second recess being lower than the top surface of the second recess such that an opening size at the top of the second recess is larger than opening sizes at the remaining positions of the second recess; and forming a metal layer in the second recesses.

The present invention also provides a metal interconnection structure, including: a substrate; a first insulating layer and a dielectric layer sequentially located on the substrate; multiple first recesses exposing the first insulating layer being formed in the dielectric layer; a second insulating layer located on the sidewalls of the first recesses with the top surface of the second insulating layer being lower than the top surfaces of the first recesses; multiple second recesses formed in the first recesses, wherein each of the second recess penetrates through the first insulating layer and is located in the substrate, an opening size at the top of each second recess being larger than opening sizes at the remaining positions of the second recess; and a metal layer located in the second recesses.

The present invention also provides a metal interconnection structure, including: a substrate; a first insulating layer and a dielectric layer sequentially located on the substrate; multiple first recesses exposing the first insulating layer being formed in the dielectric layer; a second insulating layer located on the sidewalls of the first recesses; multiple second recesses formed in the first recesses, wherein each of the second recess penetrates through the first insulating layer and extends into the substrate; and a metal layer located in the second recesses.

In the metal interconnection structure and the method for fabricating same provided by the present invention, after first recesses exposing a first insulating layer are formed, a second insulating layer is firstly formed over the sidewalls and bottoms of the first recesses. Then the second insulating layer in the first recesses, the first insulating layer, and a portion of a substrate are etched away to form second recesses. The top surface of the second insulating layer on the sidewall of each second recess is lower than the top surface of the second recess, such that an opening size at the top of the second recess is larger than opening sizes at the remaining positions of the second recess. When a metal layer is formed in the second recesses, since the opening size at the top of the second recess is increased, a window for an overhang effect at the top during metal filling can be enlarged such that the possibility of cavity formation could be reduced and the performance of the semiconductor device could be improved.

In order to make the subject matter of the present invention more apparent and more readily understandable, the subject matter of the present invention is further described below with reference to the accompanying drawings. It is a matter of course that the present invention is not limited to the specific embodiments, general substitutions well known to persons skilled in the art are also encompassed within the protection scope of the present invention.

Apparently, the described embodiments are merely a part rather than all of the embodiments of the present invention. All other embodiments obtained by persons of ordinary skill in the art based on the embodiments of the present invention without creative efforts shall fall within the protection scope of the present invention. In addition, the present invention is described in detail by using schematic diagrams. During detailed description of examples of the present invention, the figures are provided in a very simplified form and not necessarily drawn to scale, with the only intention to facilitate convenience and clarity in explaining the embodiments of the present invention, and this shall not be construed as limiting the present invention.

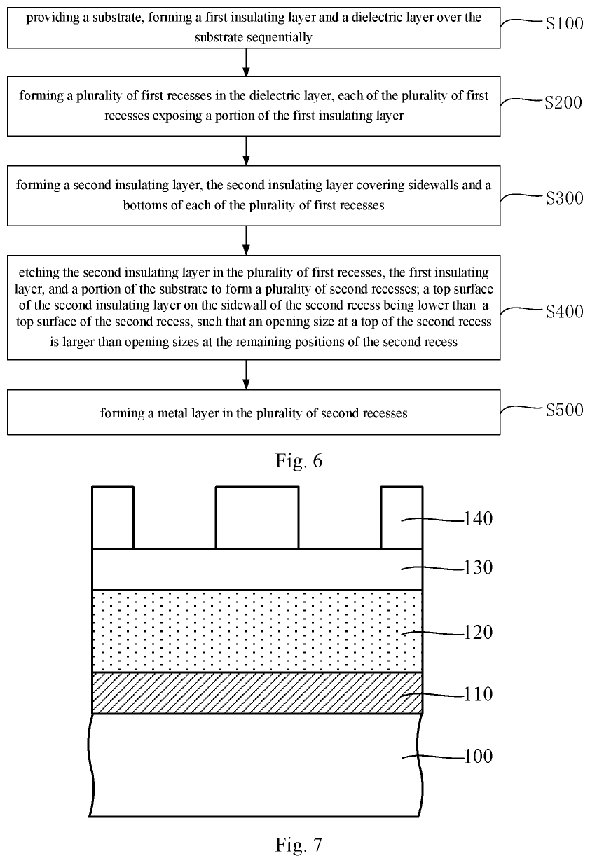

FIG. 6 is a flowchart of a method for fabricating a metal interconnection structure according to an embodiment of the present invention. FIGS. 7-13 are schematic structural diagrams of steps of a method for fabricating a metal interconnection structure according to an embodiment of the present invention. The steps of the method for fabricating a metal interconnection structure in this embodiment are described in detail below with reference to FIG. 6 and FIGS. 7-13.

In step S100, referring to FIG. 6 and FIG. 7, a substrate 100 is provided, and a first insulating layer 110 and a dielectric layer 120 are sequentially formed over the substrate 100.

The material of the substrate 100 may be single crystal silicon (Si), single crystal germanium (Ge), silicon germanium (GeSi) or silicon carbide (SiC), and may also be Silicon on Insulator (SOI) or Germanium on Insulator (GOI). Alternatively, the substrate 100 may also be formed of other materials, e.g., a group III-V compound such as gallium arsenide. In this embodiment, the material of the substrate 100 is preferably single crystal silicon (Si).

The first insulating layer 110 and the dielectric layer 120 are sequentially formed over the substrate 100. In this embodiment, the material of the first insulating layer 110 includes, but is not limited to, silicon nitride. The material of the dielectric layer 120 includes, but is not limited to, silicon oxide. For example, each of the first insulating layer 110 and the dielectric layer 120 may be formed by chemical vapor deposition.

After forming the dielectric layer 120, a hard mask layer 130 is formed over the dielectric layer 120. A photoresist layer is formed over the hard mask layer 130, and then the photoresist layer is exposed and developed to form a patterned photoresist layer 140.

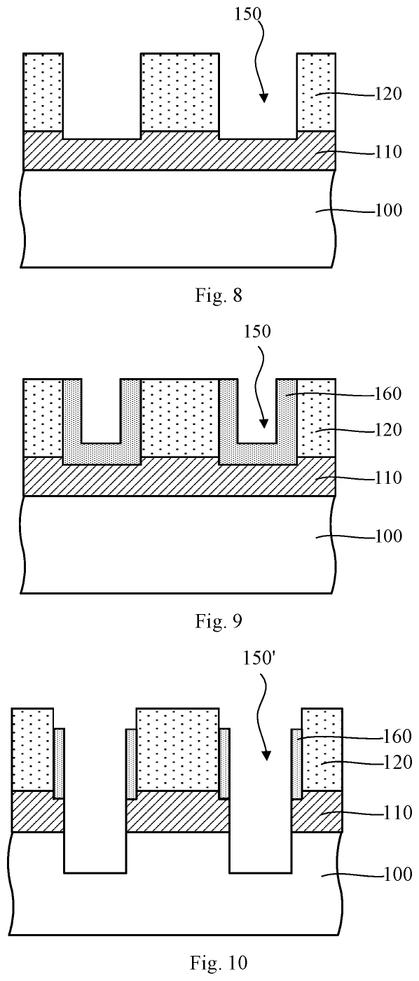

In step S200, referring to FIG. 6, and FIG. 8, multiple first recesses 150 are formed in the dielectric layer 120, and the first recesses 150 expose a portion of the first insulating layer 110.

Specifically, the hard mask layer 130 is etched by using the patterned photoresist layer 140 as a mask to form multiple openings exposing the dielectric layer 120 in the hard mask layer 130, i.e., a patterned hard mask layer is formed. Then, the patterned photoresist layer 140 is removed. Next, the dielectric layer 120 is etched by using the patterned hard mask layer as a mask to form the multiple first recesses 150. Finally, the patterned hard mask layer is removed.

The dielectric layer 120 is etched, and the etching may be stopped when the first insulating layer 110 is exposed, i.e., the first recesses 150 are completely formed in the dielectric layer 120. Preferably, in order to completely etch the dielectric layer 120 to expose the first insulating layer 110, an over etching is generally performed on the dielectric layer 120 such that the dielectric layer 120 is completely etched, and meanwhile, the first insulating layer 110 is unavoidably slightly etched. As shown in FIG. 8, that is, the first recesses 150 penetrate through the dielectric layer 120 and extend slightly into the first insulating layer 110. Alternatively, the dielectric layer 120 and a portion of the first insulating layer 110 may also be etched to form the multiple first recesses 150, i.e., the first recesses 150 penetrate through the dielectric layer 120 and extend into the first insulating layer 110. No limitation is made thereto in the present invention, but it is necessary to ensure that a partial thickness of the first insulating layer 110 is exposed at the bottoms of the first recesses 150.

In step S300, referring to FIG. 6 and FIG. 9, a second insulating layer 160 is formed, and the second insulating layer 160 covers the sidewalls and the bottoms of the first recesses 150. The material of the second insulating layer 160 is the same as that of the first insulating layer 110. In this embodiment, the material of the second insulating layer 160 includes, but is not limited to, silicon nitride.

In step S400, referring to FIG. 6, and FIG. 10, the second insulating layer 160 in the first recesses 150, the first insulating layer 110, and a portion of the substrate 100 are etched to form second recesses 150′. The top surface of the second insulating layer 160 on the sidewall of each second recess 150′ is lower than the top surface of the second recess 150′, such that an opening size at the top of the second recess 150′ is larger than opening sizes at the remaining positions of the second recess.

The second recesses 150′ are formed in the first recesses 150, penetrate through the second insulating layer 160 and the first insulating layer 110, and extend into the substrate 100. The second insulating layer 160 at the top of the sidewall of each second recess 150′ is removed to expose the dielectric layer 120, i.e., the top surface of the second insulating layer 160 on the sidewall of the second recess 150′ is lower than the top surface of the second recess 150′. Therefore, the opening size at the top of the second recess 150′ is larger than the opening sizes at the remaining positions.

Compared to FIG. 2, the opening size of the top of the second recess 150′ is increased, and therefore, during subsequent formation of a metal layer, a window for an overhang effect at the top can be enlarged such that the possibility of cavity formation could be reduced and the performance of a semiconductor device could be improved. It should be noted that, in this embodiment, the second recess 150′ is a recess required for forming a metal interconnect layer, and the size thereof is a size required by the metal interconnect layer. The size of the first recess 150 needs to be determined according to the size of the second recess 150′, the thickness of the second insulating layer 160 formed over the sidewall of the first recess 150, and the remaining thickness of the second insulating layer 160 on the sidewall of the first recess 150 after etching.

In this embodiment, the opening sizes of the second recess 150′ are smaller than 60 nm, and the opening sizes here refer to the opening sizes at the remaining positions except for the top, i.e., a metal interconnection structure with second recesses having opening sizes of smaller than 60 nm is preferably used in the method for fabricating a metal interconnection structure provided in this embodiment. Certainly, the fabrication method provided by this embodiment can also be used for second recesses having opening sizes that are greater than or equal to 60 nm. However, the opening sizes at this time are relatively large, and the probability of forming a cavity is relatively small even by using the method described in the prior art.

In step S500, referring to FIG. 6 and FIG. 13, a metal layer 180 is formed in the second recesses.

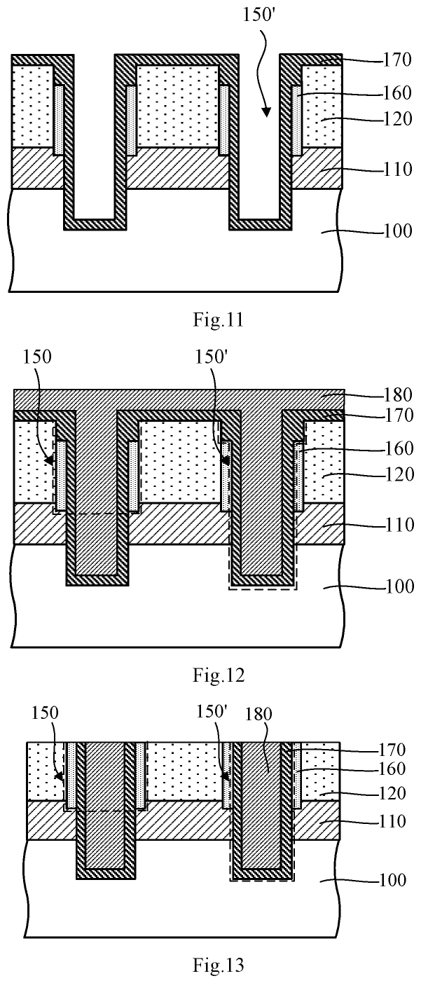

First, referring to FIG. 11, before forming the metal layer 180, a block layer 170 is firstly formed over the sidewalls and the bottoms of the second recesses 150′. The block layer 170 covers the sidewalls and bottoms of the second recesses 150′, and covers the dielectric layer 120.

In the process of forming the block layer 170, an overhang effect is occurred at the top of the sidewall of each second recess 150′ due to isotropic properties. That is, an overhang is formed at the top of the sidewall of the second recess 150′, such that the thickness of the block layer 170 at the top of the sidewall of the second recess 150′ is larger than that of the block layer 170 at the remaining sidewall and bottom of the second recess. However, since the opening size at the top of the second recess 150′ is larger than the opening sizes at the remaining positions, the overhang does not influence the opening size at the top of the second recess 150′ too much, i.e., the problem of insufficient filling due to too small openings is avoided during subsequent filling of the metal layer in the second recesses 150′.

Subsequently, a seed layer (not shown) is formed over the sidewalls and bottoms of the recesses 150′. The seed layer covers the sidewalls and bottoms of the second recesses 150′, and covers the block layer 170. Similarly, since the opening size at the top of each second recess 150′ is larger than the opening sizes at the remaining positions, the overhang formed in the process of forming the seed layer does not seal the opening of the second recess 150′, i.e., the opening size at the top of the second recess 150′ is almost the same as the opening sizes at the remaining positions of the second recess 150′.

Next, referring to FIG. 12, a metal layer 180 is formed in the second recesses 150′. In this embodiment, the metal layer 180 may be formed by electroplating. The metal layer 180 fills the second recesses 150′, and covers the seed layer. Since the opening size at the top of each second recess 150′ is almost the same as the opening sizes at the remaining positions of the second recess 150′, the generation of cavity can be avoided during filling of the metal layer 180. Finally, the metal layer 180 is planarized to expose the second insulating layer 160, forming the structure as shown in FIG. 13.

In this embodiment, the material of the block layer 170 includes, but is not limited to, titanium or titanium nitride. The material of the metal layer 180 includes, but is not limited to, copper. When the material of the metal layer 180 is copper, the seed layer is a copper seed layer.

In the method for fabricating a metal interconnection structure provided by this embodiment, after first recesses 150 exposing a first insulating layer 120 are formed, a second insulating layer 160 is firstly formed over the sidewalls and bottoms of the first recesses 150. Then the second insulating layer 160 in the first recesses 150, the first insulating layer 120, and a portion of a substrate 100 are etched away to form second recesses 150′. The top surface of the insulating layer 160 on the sidewall of each second recess 150′ is lower than the top surface of the second recess 150′, such that an opening size at the top of the second recess 150′ is larger than opening sizes at the remaining positions. When a metal layer 180 is formed in the second recesses 150′, since the opening size at the top is increased, a window for an overhang effect at the top during metal filling can be enlarged such that the possibility of cavity formation could be reduced and the performance of a semiconductor device could be improved.

Furthermore, the second insulating layer 160 is formed over the sidewalls of the second recesses 150′, i.e., the metal layers 180 filled in the adjacent second recesses 150′ are isolated by not only the dielectric layer 120 but also the second insulating layer 160, such that the diffusion of metal in the metal layers 180 can be better avoided and the pressure resistance of the metal interconnection structure can be increased. In addition, due to the increase in the opening size at the top of the second recess 150′, the process capability of a metal filling machine can be increased.

Correspondingly, the present invention also provides a metal interconnection structure, which is fabricated by the method for fabricating a metal interconnection structure as stated above. Referring to FIG. 12, the metal interconnection structure includes:

a substrate 100; a first insulating layer 110 and a dielectric layer 120 sequentially located on the substrate 100; multiple first recesses 150 exposing the first insulating layer 110 formed in the dielectric layer 120;

a second insulating layer 160 located on the sidewalls of the first recesses 150, the top surface of the second insulating layer 160 being lower than the tops of the first recesses 150;

multiple second recesses 150′ formed in the first recesses 150, wherein each of the second recess penetrates through the first insulating layer 110 and extends into the substrate 100, an opening size at the top of each second recess 150′ being larger than opening sizes at the remaining positions of the second recess 150′; and

a metal layer 180 filled in the second recesses 150′.

Preferably, the metal interconnection structure further includes: a block layer 170 located on the sidewalls and bottoms of the second recesses 150′.

Preferably, the materials of the first insulating layer 110 and the second insulating layer 160 are the same, and both include, but are not limited to, silicon nitride. The material of the dielectric layer 120 includes, but is not limited to, silicon oxide. The material of the block layer 170 includes, but is not limited to, titanium or titanium nitride. The material of the metal layer 180 includes, but is not limited to, copper.

Since an opening size at the top of the second recess 150′ is larger than opening sizes at the remaining positions of the second recess 150′, the formation of the block layer 170 and a seed layer (not shown) in the second recess 150′, and the filling of the metal layer will not produce a too small opening size at the top of the second recess 150′ caused by an overhang effect at the top, that is, the opening size at the top of the second recess 150′ is almost the same as the opening sizes at the remaining positions of the second recess 150′, thus the generation of cavity can be avoided during the filling of the metal layer 180.

Correspondingly, the present invention also provides a metal interconnection structure, which is fabricated by using the method for fabricating a metal interconnection structure as stated above. Referring to FIG. 13, the metal interconnection structure includes:

a substrate 100; a first insulating layer 110 and a dielectric layer 120 sequentially located on the substrate 100; multiple first recesses 150 exposing the first insulating layer 110 being formed in the dielectric layer 120;

a second insulating layer 160 located on the sidewalls of the first recesses 150;

multiple second recesses 150′ formed in the first recesses 150, the sidewalls of the second recesses 150′ exposing a side surface of the second insulating layer 160, the second recesses 150′ penetrating through the first insulating layer 110 and extending into the substrate 100; and a metal layer 180 located in the second recesses 150′.

Preferably, the metal interconnection structure further includes: a block layer 170 located on the sidewalls and bottoms of the second recesses 150′.

Preferably, the materials of the first insulating layer 110 and the second insulating layer 160 are the same, and both include, but are not limited to, silicon nitride. The material of the dielectric layer 120 includes, but is not limited to, silicon oxide. The material of the block layer 170 includes, but is not limited to, titanium or titanium nitride. The material of the metal layer 180 includes, but is not limited to, copper.

FIG. 13 shows a metal interconnection structure obtained after the planarization in FIG. 12: no cavity is generated in the metal layer 180. Therefore, the performance of a finally formed semiconductor device can be improved.

In conclusion, in the metal interconnection structure and the method for fabricating same provided by the present invention, after first recesses exposing a first insulating layer are formed, a second insulating layer is firstly formed over the sidewalls and bottoms of the first recesses. Then the second insulating layer in the first recesses, the first insulating layer, and a portion of a substrate are etched away to form second recesses. The top surface of the insulating layer on the sidewall of each second recess is lower than the top surface of the second recess, such that an opening size at the top of the second recess is larger than opening sizes at the remaining positions. When the metal layer is formed in the second recesses, since the opening size at the top is increased, a window for an overhang effect at the top during metal filling can be enlarged such that the possibility of cavity formation can be reduced and the performance of a semiconductor device can be improved.

Furthermore, the second insulating layer is formed over the sidewalls of the second recesses, i.e., the metal layers filled in the adjacent second recesses are isolated by not only the dielectric layer but also the second insulating layer. Therefore, the diffusion of metal in the metal layers can be better avoided, and the pressure resistance of the metal interconnection structure can be increased. In addition, due to the increased opening size at the top of the second recess, the process capability of a metal filling machine can be increased.

The foregoing description describes only preferred embodiments of the present invention, but does not limit the scope of the present invention in any sense. All changes and modifications made by persons of ordinary kill in the art according to the foregoing disclosure shall fall within the protection scope of the claims.

What is claimed is:

1. A method for fabricating a metal interconnection structure, comprising:
providing a substrate, and sequentially forming a first insulating layer and a dielectric layer over the substrate;
forming a plurality of first recesses in the dielectric layer, each of the plurality of first recesses exposing a portion of the first insulating layer;
forming a second insulating layer, the second insulating layer covering sidewalls and a bottom of each of the plurality of first recesses;
etching, in the plurality of first recesses, the second insulating layer, the first insulating layer, and a portion of the substrate to form a plurality of second recesses; a top surface of the second insulating layer on the sidewall of the second recess being lower than a top surface of the second recess such that an opening size at a top of the second recess is larger than opening sizes at remaining positions of the second recess; and
forming a metal layer in the plurality of second recesses.

2. The method for fabricating a metal interconnection structure according to claim 1, wherein prior to forming the metal layer, the method further comprises: forming a block layer over sidewalls and a bottom of each of the plurality of second recesses.

3. The method for fabricating a metal interconnection structure according to claim 2, wherein forming the metal layer comprises:
filling the plurality of second recesses with the metal layer, the metal layer also covering the dielectric layer; and
planarizing the metal layer to expose the second insulating layer.

4. The method for fabricating a metal interconnection structure according to claim 1, wherein a material of the first insulating layer is same as a material of the second insulating layer.

5. The method for fabricating a metal interconnection structure according to claim 4, wherein each of the first and second insulating layers is a silicon nitride layer, the dielectric layer being a silicon oxide layer.

6. The method for fabricating a metal interconnection structure according to claim 1, wherein forming the plurality of first recesses comprises:
forming a hard mask layer and a patterned photoresist layer over the dielectric layer;
etching the hard mask layer, by using the patterned photoresist layer as a mask, to form a plurality of openings exposing the dielectric layer;
removing the patterned photoresist layer;
etching the dielectric layer, by using the hard mask layer in which the plurality of openings are formed as a mask, to form the plurality of first recesses; and
removing the hard mask layer.

7. The method for fabricating a metal interconnection structure according to claim 6, wherein the dielectric layer is completely etched away to form the plurality of first recesses.

8. A metal interconnection structure, comprising:
a substrate;
a first insulating layer and a dielectric layer sequentially located on the substrate;
a plurality of first recesses formed in the dielectric layer, the plurality of first recesses exposing the first insulating layer;
a second insulating layer located on sidewalls of each of the plurality of first recesses, a top surface of the second insulating layer being lower than a top surface of the first recess;
a plurality of second recesses formed in the first recesses, wherein each of the second recess penetrates through the first insulating layer and extends into the substrate, an opening size at a top of the second recess being larger than opening sizes at remaining positions of the second recess; and
a metal layer located in the plurality of second recesses.

9. The metal interconnection structure according to claim 8, further comprising:
a block layer located on the sidewalls and a bottom of each of the plurality of second recesses.

10. The metal interconnection structure according to claim 8, wherein a material of the first insulating layer is same as a material of the second insulating layer.

11. A metal interconnection structure, comprising:
a substrate;
a first insulating layer and a dielectric layer sequentially located on the substrate;
a plurality of first recesses formed in the dielectric layer, the plurality of first recesses exposing the first insulating layer;
a second insulating layer located on sidewalls of the plurality of first recesses;
a plurality of second recesses formed in the plurality of first recesses, wherein each of the plurality of second recesses penetrates through the first insulating layer and extends into the substrate; and
a metal layer located in the plurality of second recesses.
